(19) United States
(12) Patent Application Publication
(10) Pub. No.: US 2002/0033250 A1
(43) Pub. Date: Mar. 21, 2002

(54) Heat conductive apparatus

(76) Inventor: Chia-Chin Chuang, Taipei (TW)

Correspondence Address: INTELLECTUAL PROPERTY SOLUTIONS, P.L.L.C., 1300 PENNSYLVANIA AVENUE N.W., SUITE 700, WASHINGTON, DC, 20004, US

(21) Appl. No.: 09/953,221

(22) Filed: Sep. 17, 2001

(30) Foreign Application Priority Data
Sep. 21, 2000 (TW) 89119448

(51) Int. Cl. F28D 15/00; H05K 7/20

(52) U.S. Cl. 165/104.33; 361/700

(57) ABSTRACT

The present invention relates to a heat conductive apparatus, and more specifically, to an apparatus for conducting heat from a high-temperature area to a low-temperature area. The heat conductive apparatus has a sealed space containing a cooling medium, and the cooling medium is provided at appropriate pressure conditions below room temperature to approach the liquid-gas phase critical state and perform rapid heat convection in the heat conductive apparatus in the presence of local temperature differential. In addition, the present invention increases the contact area between the cooling medium and the housing of the heat conductive apparatus by a specific internal structure, so that heat can be rapidly conducted to the heat conductive apparatus to achieve a better effect than that of conventional heat conductive apparatus with additional devices, such as compressors.

### BACKGROUND OF THE INVENTION

1. Field of the Invention

The present invention relates to a heat conductive apparatus, and more specifically, to an apparatus for conducting heat from a high-temperature area to a low-temperature area.

2. Description of the Related Art

Application of heat conductive apparatus in various devices, such as heat conductive pipes in cooling and refrigeration devices (air conditioners, refrigerators) and heating devices (central heating systems) or dissipating blocks and fins in heat dissipation systems, is well known and widely used.

According to experience, it is necessary to use a material with higher heat conductivity for a heat conductor to achieve better heat transfer performance. If a further enhancement of heat transferring speed is preferred, there is a conventional process applying fluid motion to transfer heat rapidly; that is, by applying heat convection, better heat transfer performance is further enhanced.

There are various fluid applications in the heat transfer field. In these applications, it is necessary to apply kinetic energy to the fluid for the fluid motion; thus, additional devices such as compressors, fans and valves are required in the conventional heat transfer/conductive system. However, these additional devices increase difficulties of system space arrangement, production cost and maintenance. As a result, a heat conductive apparatus that performs similar heat transfer effect without additional devices for fluid motions is preferred.

In the field of thermodynamics, it is well known that fluid contained in a sealed vessel (that is in an isometric condition) may undergo significant pressure change with slight variation in temperature under the boundary condition of a liquid-gas phase critical state (a specific temperature-pressure curve), also referred to as a super-critical fluid state. Therefore, if any temperature differential exists within the sealed vessel's contents, corresponding pressure difference will cause rapid fluid motion; that is, any partial temperature differential within the fluid in the sealed vessel will reach a balance rapidly with the effect of heat convection.

### SUMMARY OF THE INVENTION

In order to utilize the above-mentioned principle, a sealed space containing a cooling medium is provided in the heat conduction apparatus of the present invention, and the cooling medium is set to an appropriate pressure condition below room temperature to obtain the above-mentioned effect. In addition, according to heat transfer principles, the heat conduction rate is substantially in proportion to the contact surface area. As a result, the present invention increases the contact area between the cooling medium and the housing of the heat conductive apparatus by a specific internal structure, so that heat can be rapidly transferred from one end to another end of the heat conductive apparatus to achieve a better heat conductive effect with the help of the cooling medium.

As mentioned above, the first embodiment of the present invention discloses a heat conductive apparatus for conducting the heat from a high-temperature area to a low-temperature area. The heat conductive apparatus comprises: a heat conductive block having a first opening end, a second opening end, and a hollow area extending between the first opening end and the second opening end; a cold-end conductor sealing the first opening end and contacting the low-temperature area; a hot-end conductor sealing the second opening end and contacting the high-temperature area; and a cooling medium contained in the sealed chamber under a certain condition for assimilating the heat and performing phase change.

The second embodiment of the present invention discloses a heat conductive apparatus for conducting the heat from a high-temperature area to a low-temperature area. Compared to the first embodiment of the present invention, the heat conductive apparatus further comprises: a plurality of first heat conductive strips each having a first end and a second end, the first end of each first heat conductive strip disposed on the cold-end conductor toward the hollow area, and the second end of each first heat conductive strip disposed substantially toward the heat-end conductor; and a plurality of second heat conductive strips each having a third end and a fourth end, the third end of each second heat conductive strip disposed on the heat-end conductor toward the hollow area, and the fourth end of each second heat conductive strip disposed substantially toward the cold-end conductor, wherein certain spaces are respectively formed between the first heat conductive strips and the second heat conductive strips.

The third embodiment of the present invention discloses a heat conductive apparatus for conducting the heat from a high-temperature area to a low-temperature area. Compared to the first embodiment of the present invention, the heat conductive apparatus further comprises: a plurality of heat conductive strips each having a first end and a second end, the first end of each first heat conductive strip disposed on the cold-end conductor toward the hollow area, and the second end of each first heat conductive strip disposed on the heat-end conductor toward the hollow area, wherein certain spaces are respectively formed between the heat conductive strips.

In the above-mentioned embodiments of the present invention, the heat conductive block within the hollow area may further have an inner peripheral wall provided in the hollow area, and a plurality of ridges extending between the first opening end and the second opening end may be provided on the inner peripheral wall. Further, the heat conductive block, the ridges, the cold-end conductor, the hot-end conductor, and the heat conductive strips in the second and third embodiments may be respectively made of heat conductive materials. Further, the heat conductive materials can be selected from the group consisting of copper, aluminum, titanium, copper alloy, aluminum alloy, titanium alloy, and stainless steel. Further, the first and second heat conductive strips in the second embodiment or the heat conductive strips in the third embodiment may be respective board-shaped components, or may comprise a plurality of protrusions of the heat conductive materials provided on the heat conductive strips, or may respectively have a hollow portion forming a tube structure. Further, if the first and second heat conductive strips in the second embodiment or the heat conductive strips in the third embodiment respectively have a hollow portion forming a tube structure, there may be a plurality of heat conductive meshes of the heat conductive materials contained in the hollow portions.

### BRIEF DESCRIPTION OF THE DRAWINGS

The present invention can be more fully understood by reading the subsequent detailed description in conjunction with the examples and references made to the accompanying drawings, wherein:

FIG. 1 is a perspective view according to the first embodiment of the present invention;

FIG. 2 is a perspective cross-sectional exploded view of FIG. 1;

FIG. 3 is a cross-sectional view of FIG. 1;

FIG. 4 is a perspective view according to the second embodiment of the present invention;

FIGS. 5a and 5b are cross-sectional views of FIG. 4;

FIGS. 6 is a schematic view of the inner configuration according to the second embodiment of the present invention;

FIG. 7a and 7b are cross-sectional views according to the third embodiment of the present invention; and

FIG. 8 is a schematic view of the inner configuration according to the third embodiment of the present invention.

### DETAILED DESCRIPTION OF THE PREFERRED EMBODIMENT

The present invention will be hereinafter described with three embodiments.

First Embodiment

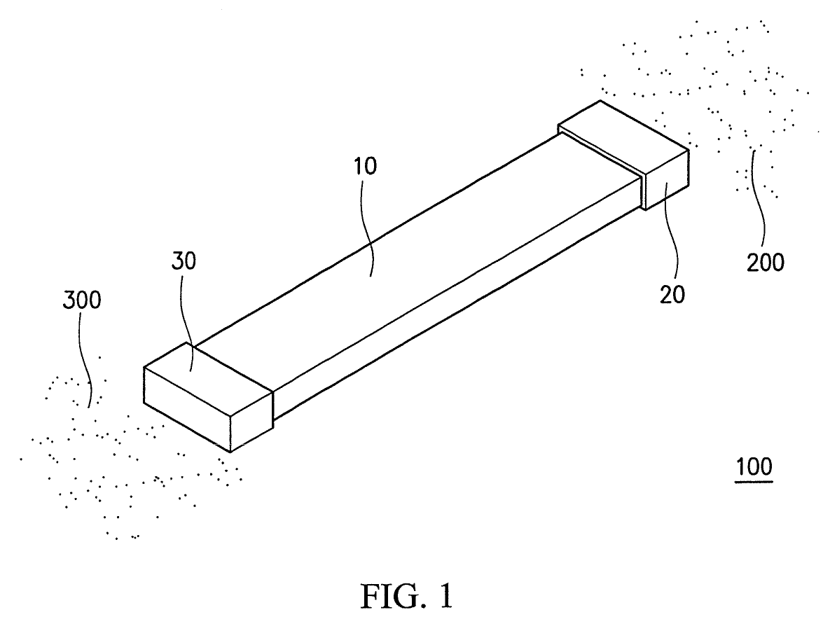

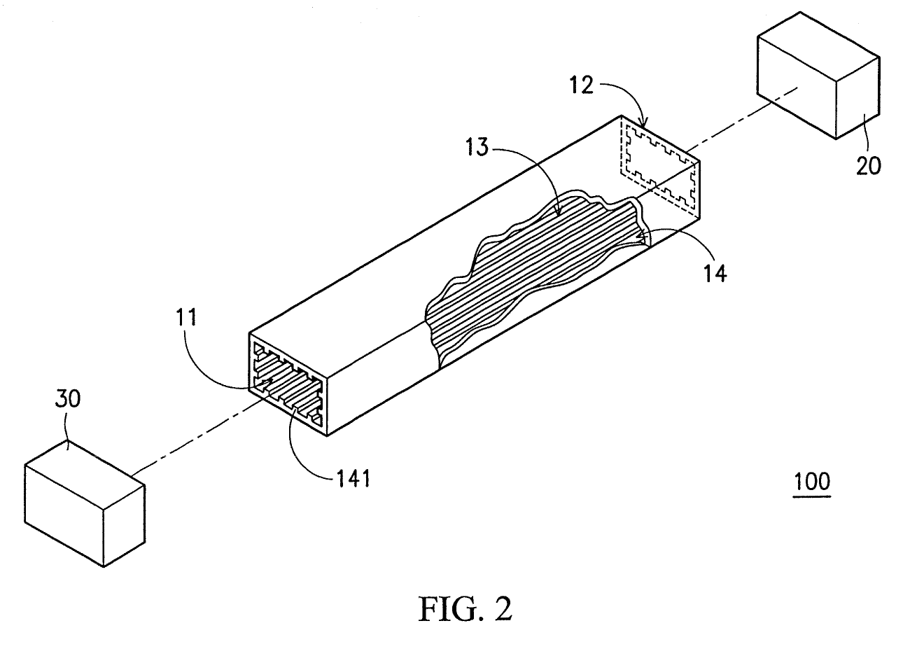

FIG. 1 to FIG. 3 shows the first embodiment of the present invention. A heat conductive apparatus 100 is shown in FIG. 1, which comprises a heat conductive block 10, a hot-end conductor 20 contacting a high-temperature area 200, and a cold-end conductor 30 contacting a cold-temperature area 300. The inner structure of the first embodiment is shown in FIG. 2. The heat conductive block 10 is a hollow component, which has a first opening end 11 connected to the cold-end conductor 30, and a second opening end 12 connected to the hot-end conductor 20. A hollow area 13 is in the heat conductive block 10, and an inner peripheral wall 14 is disposed on the heat conductive block 10 within the hollow area 13.

In practical manufacture, it is preferred that the heat conductive apparatus 100 be fabricated in the three components 10, 20 and 30, and composed usibg, for example, a welding process.

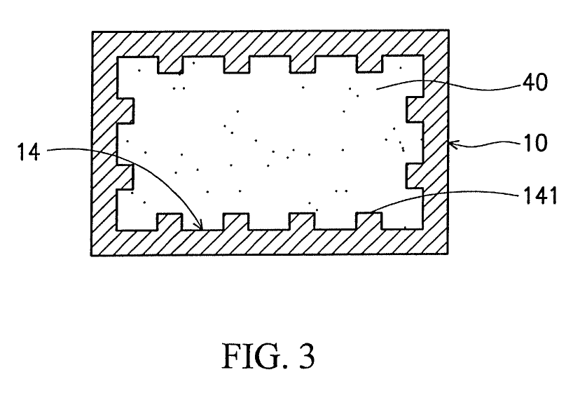

Specifically, in the first embodiment, the hollow area 13 is filled with a cooling medium 40, as shown in FIG. 3. The cooling medium 40 transfers heat in the heat conductive apparatus 100 mainly by heat convection. In order to perform the desired effect, it is preferred to have the cooling medium 40 sealed in the hollow portion 13 under a condition approaching liquid-gas phase critical pressure (in which the temperature is below room temperature). To achieve this, for example, the system may be composed in a closed space at the specific pressure.

It is known that the heat conduction rate is substantially in proportion to the contact surface area; therefore, it is preferred that the inner peripheral wall 14 has a plurality of ridges 141 to increase the contact surface area between the cooling medium 40 and the heat conductive block 10 for better heat transfer. In addition, the heat conductive block 10, the cold-end conductor 30, the hot-end conductor 20, and the ridges 141 may be respectively made of heat conductive materials, such as copper, aluminum, titanium, copper alloy, aluminum alloy, titanium alloy, stainless steel, or other heat conductive materials, and each of the components may be made of different materials.

Second Embodiment

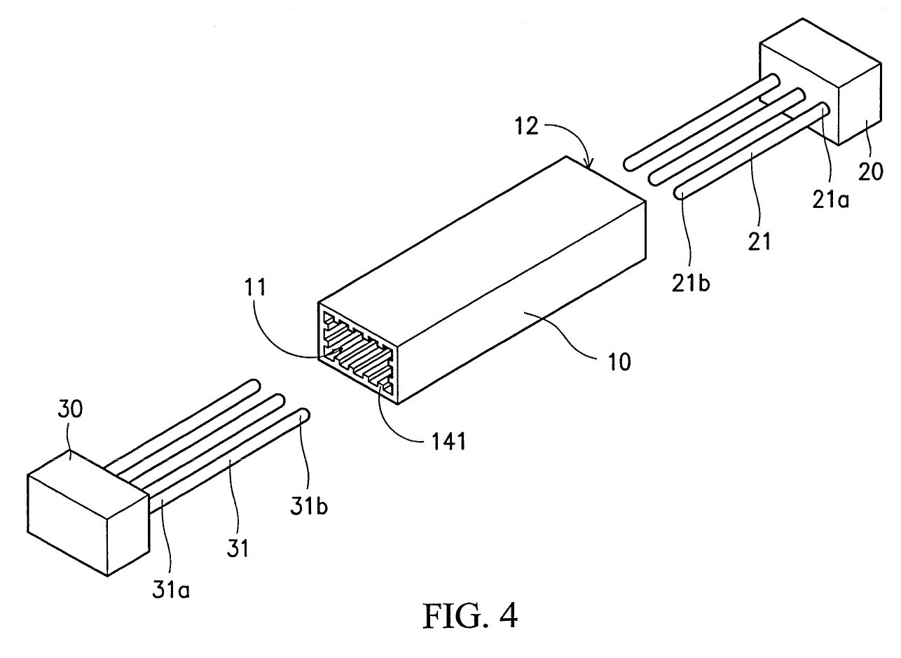

The second embodiment of the present invention has a similar configuration to the above-mentioned first embodiment, with the second embodiment having additional first heat conductive strips 31 and second heat conductive strips 21. As shown in FIG. 4, the cold-end conductor 30 has a plurality of first heat conductive strips 31 (three strips in this embodiment), and the hot-end conductor 20 has a plurality of second heat conductive strips 21 (three strips in this embodiment). Each of the first heat conductive strips 31 has a first end 31a and a second end 31b, the first end 31a disposed on the cold-end conductor 30, and the second end 31b extending substantially toward the hot-end conductor 20 while the components are in combination. Each of the second heat conductive strips 21 has a third end 21a and a fourth end 21b, the third end 21a disposed on the hot-end conductor 20, and the fourth end 21b extending substantially toward the cold-end conductor 30 while the components are in combination.

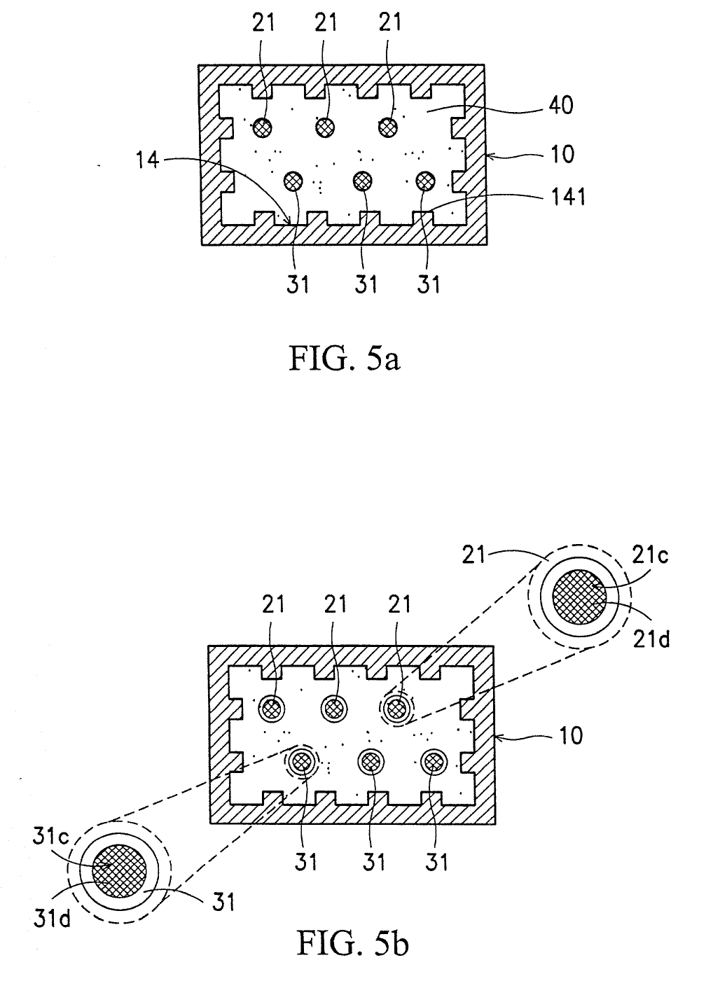

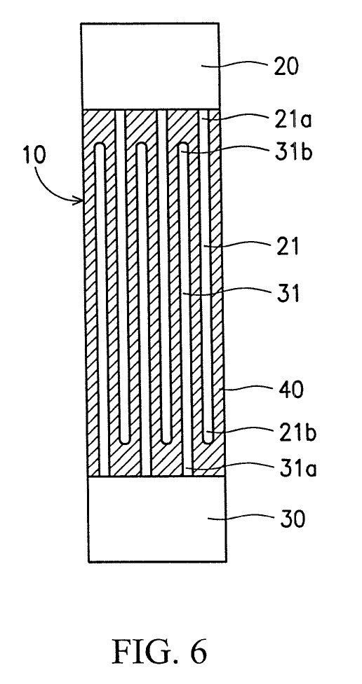

The inner configuration of the second embodiment is shown in FIG. 6. Similar to the first embodiment, the hollow area 13 is filled with a cooling medium 40, as shown in FIG. 5a. The cooling medium 40 transfers heat in the heat conductive apparatus 100 mainly by heat convection. In order to perform the desired effect, it is preferred to have the cooling medium 40 sealed in the hollow portion 13 under a condition approaching liquid-gas phase critical pressure (in which the temperature is below room temperature). To achieve this, for example, the system may be composed in a closed space at the specific pressure.

The size and quantity of the first and second heat conductive strips 31 and 21 and the space between the strips 31 and 21 will determine heat conductive conditions between the heat conductive system and the cooling medium 40. For example, in FIG. 5a, if the total area of the sectional areas (the circle areas shown with slant lines) of the first heat conductive strips 31 (and the second heat conductive strips 21) is constant, the overall surface area of the first and second heat conductive strips 31 and 21 will be increased when the quantity of strips increases, thus better heat conduction is achieved. That is, the first and second heat conductive strips 31 and 21 can be made thinner to achieve better effect.

Further, experiments with heat transfer have proven that the space between the first and second heat conductive strips 31 and 21 can be made smaller to achieve better heat transfer. If the space is so small that the cooling medium 40 therein approaches a film state, the local temperature change may cause the system to produce a heat pulse, producing enormous heat transfer effects.

In addition, it is preferred to provide ridges 141 on the inner peripheral wall 14 of the hollow area 13, as shown in FIG. 5a, in order to further increase the contact area between the heat conductive system and the cooling medium 40. The ridges 141 can be extending between the first opening end 11 and the second opening end 12.

The heat conductive block 10, the cold-end conductor 30, the hot-end conductor 20, the first and second heat conductive strips 31 and 21, and the ridges 141 may be respectively made of heat conductive materials, such as copper, aluminum, titanium, copper alloy, aluminum alloy, titanium alloy, stainless steel, or other heat conductive materials, and each of the components may be made of different materials.

Further, the first heat conductive strips 31 and the second heat conductive strips 21 can be board-shaped components (not shown); it is also acceptable to have the first and second heat conductive strips 31 and 21 respectively having a plurality of protrusions (not shown) thereon; or, the first and second heat conductive strips 31 and 21 may respectively have hollow portions 31c and 21c in order to respectively form a tube structure as shown in FIG. 4b. If the first heat conductive strips 31 and the second heat conductive strips 21 have hollow portions 31c and 21c, it is also acceptable to contain a plurality of heat conduction meshes 31d and 21d in the hollow portions 31c and 21c, so that the total area of heat conduction will be increased.

Third Embodiment

The third embodiment of the present invention has a similar configuration to the above-mentioned embodiments, except the heat conductive strips 50. In the third embodiment, a plurality of heat conductive strips 50 (six strips in this embodiment) is provided in the hollow area 13. Each of the heat conductive strips 50 has a first end 50a disposed on the cold-end conductor 30, and a second end 50b disposed on the hot-end conductor 20.

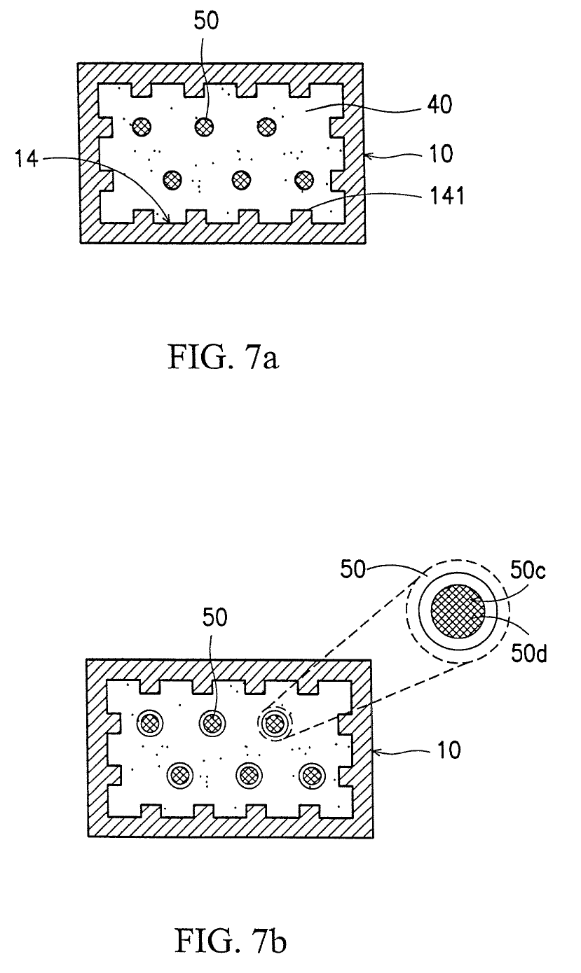

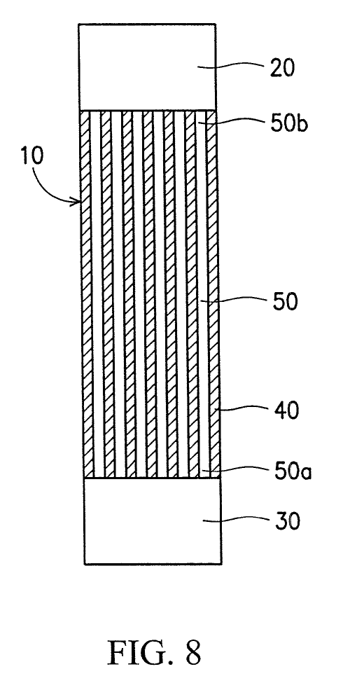

The inner configuration of the second embodiment is shown in FIG. 8. Similar to the second embodiment, the hollow area 13 is filled with a cooling medium 40, as shown in FIG. 7a. The cooling medium 40 transfers heat in the heat conductive apparatus 100 mainly by heat convection. In order to perform the desired effect, it is preferred to have the cooling medium 40 sealed in the hollow portion 13 under a condition approaching liquid-gas phase critical pressure (in which the temperature is below room temperature). To achieve this, for example, the system may be composed in a closed space at the specific pressure.

The size and quantity of the heat conductive strips 50 and the space between the strips 50 will determine heat conductive conditions between the heat conductive system and the cooling medium 40. For example, in FIG. 5a, if the total area of the sectional areas (the circle areas shown with slant lines) of the heat conductive strips 50 is constant, the overall surface area of the heat conductive strips 50 will be increased when the quantity of strips increases, thus better heat conduction is achieved. That is, the heat conductive strips 50 can be made thinner to achieve better effect.

Further, experiments with heat transfer have proven that the space between the heat conductive strips 50 can be made smaller to achieve better heat transfer. If the space is so small that the cooling medium 40 therein approaches a film state, the local temperature change may cause the system to produce a heat pulse, producing enormous heat transfer effects.

In addition, it is preferred to provide ridges 141 on the inner peripheral wall 14 of the hollow area 13, as shown in FIG. 7a, in order to further increase the contact area between the heat conductive system and the cooling medium 40. The ridges 141 can be extending between the first opening end 11 and the second opening end 12.

The heat conductive block 10, the cold-end conductor 30, the hot-end conductor 20, the heat conductive strips 50, and the ridges 141 may be respectively made of heat conductive materials, such as copper, aluminum, titanium, copper alloy, aluminum alloy, titanium alloy, stainless steel, or other heat conductive materials, and each of the components may be made of different materials.

Further, the heat conductive strips 50 can be board-shaped components (not shown); it is also acceptable to have the heat conductive strips 50 respectively having a plurality of protrusions (not shown) thereon; or, the heat conductive strips 50 may respectively have a hollow portion 50c in order to respectively form a tube structure as shown in FIG. 7b. If each of the heat conductive strips 50 has a hollow portion 50c, it is also acceptable to contain a plurality of heat conduction meshes 50d in the hollow portions 50c, so that the total area of heat conduction will be increased.

The above-mentioned embodiments are utilized by contacting the hot-end conductor 20 to the heat source (high-temperature area 200) and transferring heat to the cold area (low-temperature area 300) contacted by the cold-end conductor 30. The cooling medium 40 near the heat source approaches the liquid-gas phase critical state and performs the above-mentioned rapid heat convection in the presence of local temperature differential in the heat source; and the cooling medium 40 near the cold-end conductor 30 has a local pressure loss due to the temperature drop. As a result, the heat conductive apparatus 100 has a system inside for continuously producing convection with internal pressure difference.

The heat conductive apparatus of the present invention has a system for continuously producing rapid heat convection with temperature difference, which is superior to the conventional heat conductive/transfer systems with additional devices, such as compressors. In addition, the present invention can be applied in various aspects, such as air conditioners, central heating systems, engines, refrigerators, CPU heat dissipation devices, or other devices with the need of heat transfer.

While the present invention has been described with reference to the preferred embodiments thereof, it is to be understood that the invention is not limited to the described embodiments or constructions. On the contrary, the invention is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A heat conductive apparatus for conducting the heat from a high-temperature area to a low-temperature area, the heat conductive apparatus comprising:
a heat conductive block having a first opening end, a second opening end, and a hollow area extending between the first opening end and the second opening end;
a cold-end conductor sealing the first opening end and contacting the low-temperature area;
a hot-end conductor sealing the second opening end and contacting the high-temperature area; and
a cooling medium contained in the sealed chamber under a certain condition for assimilating the heat and performing phase change.

2. The heat conductive apparatus according to claim 1, wherein the heat conductive block within the hollow area further has an inner peripheral wall provided in the hollow area, and a plurality of ridges extending between the first opening end and the second opening end is provided on the inner peripheral wall.

3. The heat conductive apparatus according to claim 2, wherein the heat conductive block, the ridges, the cold-end conductor and the hot-end conductor are respectively made of heat conductive materials.

4. The heat conductive apparatus according to claim 3, wherein the heat conductive materials are selected from the group consisting of copper, aluminum, titanium, copper alloy, aluminum alloy, titanium alloy, and stainless steel.

5. A heat conductive apparatus for conducting the heat from a high-temperature area to a low-temperature area, the heat conductive apparatus comprising:
a heat conductive block having a first opening end, a second opening end, and a hollow area extending between the first opening end and the second opening end;
a cold-end conductor sealing the first opening end and contacting the low-temperature area;
a hot-end conductor sealing the second opening end and contacting the high-temperature area;
a plurality of first heat conductive strips each having a first end and a second end, the first end of each first heat conductive strip disposed on the cold-end conductor toward the hollow area, and the second end of each first heat conductive strip disposed substantially toward the heat-end conductor;
a plurality of second heat conductive strips each having a third end and a fourth end, the third end of each second heat conductive strip disposed on the heat-end conductor toward the hollow area, and the fourth end of each second heat conductive strip disposed substantially toward the cold-end conductor, wherein certain spaces are respectively formed between the first heat conductive strips and the second heat conductive strips; and
a cooling medium contained in the sealed chamber under a certain condition for assimilating the heat and performing phase change.

6. The heat conductive apparatus according to claim 5, wherein the heat conductive block within the hollow area further has an inner peripheral wall provided in the hollow area, and a plurality of ridges extending between the first opening end and the second opening end is provided on the inner peripheral wall.

7. The heat conductive apparatus according to claim 6, wherein the heat conductive block, the first heat conductive strips, the second heat conductive strips, the ridges, the cold-end conductor and the hot-end conductor are respectively made of heat conductive materials.

8. The heat conductive apparatus according to claim 7, wherein the heat conductive materials are selected from the group consisting of copper, aluminum, titanium, copper alloy, aluminum alloy, titanium alloy, and stainless steel.

9. The heat conductive apparatus according to claim 8, wherein the first heat conductive strips and the second heat conductive strips are respective board-shaped components.

10. The heat conductive apparatus according to claim 8, further comprising a plurality of protrusions of the heat conductive materials provided on the first heat conductive strips and the second heat conductive strips.

11. The heat conductive apparatus according to claim 8, wherein each of the first heat conductive strips and the second heat conductive strips respectively has a hollow portion forming a tube structure.

12. The heat conductive apparatus according to claim 11, further comprising a plurality of heat conductive meshes of the heat conductive materials contained in the hollow portions.

13. A heat conductive apparatus for conducting the heat from a high-temperature area to a low-temperature area, the heat conductive apparatus comprising:
a heat conductive block having a first opening end, a second opening end, and a hollow area extending between the first opening end and the second opening end;
a cold-end conductor sealing the first opening end and contacting the low-temperature area;
a hot-end conductor sealing the second opening end and contacting the high-temperature area;
a plurality of heat conductive strips each having a first end and a second end, the first end of each first heat conductive strip disposed on the cold-end conductor toward the hollow area, and the second end of each first heat conductive strip disposed on the heat-end conductor toward the hollow area, wherein certain spaces are respectively formed between the heat conductive strips; and
a cooling medium contained in the sealed chamber under a certain condition for assimilating the heat and performing phase change.

14. The heat conductive apparatus according to claim 13, wherein the heat conductive block within the hollow area further has an inner peripheral wall provided in the hollow area, and a plurality of ridges extending between the first opening end and the second opening end is provided on the inner peripheral wall.

15. The heat conductive apparatus according to claim 14, wherein the heat conductive block, the heat conductive strips, the ridges, the cold-end conductor and the hot-end conductor are respectively made of heat conductive materials.

16. The heat conductive apparatus according to claim 15, wherein the heat conductive materials are selected from the group consisting of copper, aluminum, titanium, copper alloy, aluminum alloy, titanium alloy, and stainless steel.

17. The heat conductive apparatus according to claim 16, wherein the heat conductive strips are board-shaped components.

18. The heat conductive apparatus according to claim 16, further comprising a plurality of protrusions of the heat conductive materials provided on the heat conductive strips.

19. The heat conductive apparatus according to claim 16, wherein each of the heat conductive strips respectively has a hollow portion forming a tube structure.

20. The heat conductive apparatus according to claim 19, further comprising a plurality of heat conductive meshes of the heat conductive materials contained in the hollow portions.
